(19) United States
(12) Patent Application Publication
(10) Pub. No.: US 2017/0077326 A1
(43) Pub. Date: Mar. 16, 2017

(54) PHOTOELECTRIC CONVERSION ELEMENT, SOLAR BATTERY, SOLAR BATTERY MODULE, AND SOLAR POWER GENERATION SYSTEM

(71) Applicant: KABUSHIKI KAISHA TOSHIBA, Tokyo (JP)

(72) Inventors: Soichiro Shibasaki, Nerima Tokyo (JP); Hiroki Hiraga, Saitama Saitama (JP); Naoyuki Nakagawa, Setagaya Tokyo (JP); Miyuki Shiokawa, Kawasaki Kanagawa (JP); Hitomi Saito, Kawaguchi Saitama (JP); Mutsuki Yamazaki, Yokohama Kanagawa (JP); Kazushige Yamamoto, Yokohama Kanagawa (JP)

(21) Appl. No.: 15/256,901

(22) Filed: Sep. 6, 2016

(30) Foreign Application Priority Data
Sep. 16, 2015 (JP) 2015-182571

(51) Int. Cl. H01L 31/032; H01L 31/0445; H01L 31/047

(52) U.S. Cl. CPC H01L 31/0322; H01L 31/047; H01L 31/0445

(57) ABSTRACT

A photoelectric conversion element of an embodiment includes a first electrode, a second electrode, and a light-absorbing layer containing a chalcopyrite-type compound containing a group Ib element, a group IIIb element, and a group VIb element between the first electrode and the second electrode. A region in which concentration of the group Ib element in the light-absorbing layer is from 0.1 to 10 atom %, both inclusive, is included in a region up to a depth of 10 nm in a direction from a principal plane of the light-absorbing layer on a side of the second electrode to a side of the first electrode.

### CROSS-REFERENCE TO RELATED APPLICATION

This application is based upon and claims the benefit of priority from Japanese Patent Application No. 2015-182571, filed on Sep. 16, 2015; the entire contents of which are incorporated herein by reference.

### FIELD

Embodiments described herein relate to a photoelectric conversion element, a solar battery, a solar battery module, and a solar power generation system.

### BACKGROUND

Development of compound photoelectric conversion elements using a semiconductor thin film as a light-absorbing layer has been in progress. Among them, thin film photoelectric conversion elements using a p-type semiconductor layer having a chalcopyrite structure as the light-absorbing layer exhibit high conversion efficiency, and are expected for applications. To be specific, in thin film photoelectric conversion elements using Cu (In, Ga) Se₂ made of Cu—In—Ga—Se, Cu(In, Al)Se₂ made of Cu—In—Al—Se, Cu(Al, Ga) Se₂ made of Cu—Al—Ga—Se, and CuGaSe₂ made of Cu—Ga—Se as the light-absorbing layer, the high conversion efficiency is obtained. Typically, a thin film photoelectric conversion element using a p-type semiconductor layer having a chalcopyrite structure, a Kesterite structure, or a Stannite structure as the light-absorbing layer has a structure in which a molybdenum lower electrode, a p-type semiconductor layer, an n-type semiconductor layer, an insulating layer, a transparent electrode, an upper electrode, and an antireflective film are laminated on a soda-lime glass serving as a substrate. The conversion efficiency η is expressed by:

H=Voc·Jsc·FF/P·100,

using an open circuit voltage Voc, short-circuit current density Jsc, an output factor FF, and incident power density P.

### BRIEF DESCRIPTION OF THE DRAWINGS

FIG. 1 is a sectional conceptual diagram of a thin film photoelectric conversion element according to an embodiment;

FIG. 2 is a sectional conceptual diagram of a multijunction-type photoelectric conversion element according to an embodiment;

FIG. 3 is a sectional conceptual diagram of a solar battery module according to an embodiment; and

FIG. 4 is a sectional conceptual diagram of a solar power generation system according to an embodiment.

### DETAILED DESCRIPTION

A photoelectric conversion element of an embodiment includes a first electrode, a second electrode, and a light-absorbing layer containing a chalcopyrite-type compound containing a group Ib element, a group IIIb element, and a group VIb element between the first electrode and the second electrode. A region in which concentration of the group Ib element in the light-absorbing layer is from 0.1 to 10 atom %, both inclusive, is included in a region up to a depth of 10 nm in a direction from a principal plane of the light-absorbing layer on a side of the second electrode to a side of the first electrode.

Hereinafter, a favorable embodiment will be described in detail with reference to the drawings.

(Photoelectric Conversion Element)

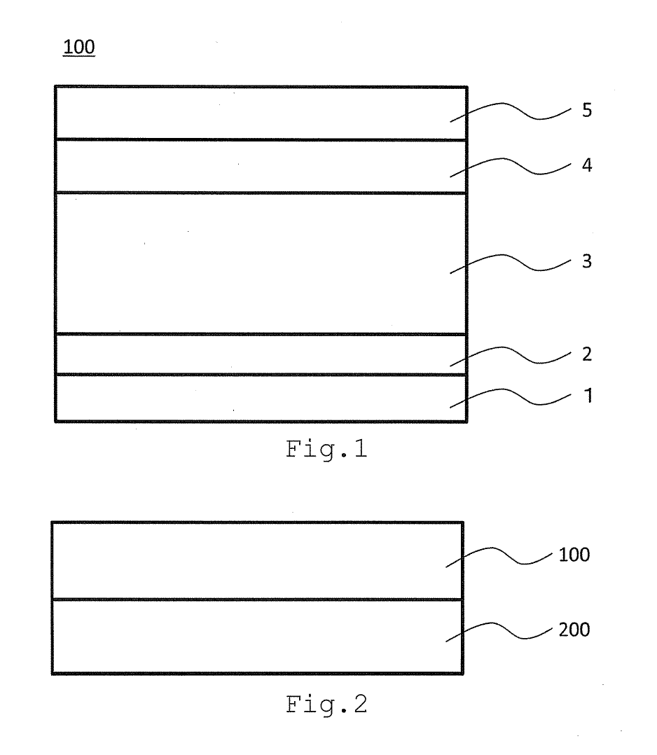

A photoelectric conversion element 100 according to the present embodiment illustrated in the conceptual diagram of FIG. 1 includes a substrate 1, a first electrode 2 formed on the substrate 1, a light-absorbing layer 3 formed on the first electrode, an n layer 4 formed on the light-absorbing layer 3, and a second electrode 5 formed on the n layer 4. To be specific, an example of the photoelectric conversion element 100 includes a solar battery. The photoelectric conversion element 100 of the embodiment is joined with another photoelectric conversion element 200, as illustrated in FIG. 2, thereby to have a multijunction-type structure. The light-absorbing layer of the photoelectric conversion element 100 has favorably a wider gap than the light-absorbing layer of the photoelectric conversion element 200. The light-absorbing layer of the photoelectric conversion element 200 uses Si, for example. To be specific, an example of the multijunction-type photoelectric conversion element includes a solar battery.

(Substrate)

For the substrate 1 of the embodiment, soda-lime glass is favorably used. Various types of glass such as quarts, super white glass, and chemically strengthened glass, stainless steel, a metal plate made of titanium (Ti) or chromium (Cr), or a resin such as a polyimide resin or an acrylic resin may be used.

(First Electrode)

The first electrode 2 of the embodiment is an electrode of the photoelectric conversion element 100, and is a first metal film or a semiconductor film formed on the substrate 1. As the lower electrode 2, a conductive metal film (first metal film) containing Mo, W, or the like, or a semiconductor film containing at least indium-tin oxide (ITO) can be used. The first metal film is favorably an Mo film or a W film. A layer containing an oxide such as SnO₂, TiO₂, carrier-doped ZnO:Ga or carrier-doped ZnO:Al may be laminated on the ITO on a side of the light-absorbing layer 3. In a case of using the semiconductor film as the first electrode 2, a layer in which ITO and SnO₂ are laminated from a side of the substrate 1 to the side of the light-absorbing layer 3, or a layer in which ITO, SnO₂, and TiO₂ are laminated from the side of the substrate 1 to the side of the light-absorbing layer 3 may be used. Further, a layer containing an oxide such as SiO₂ may be further provided between the substrate 1 and ITO. The first electrode 2 can be formed by sputtering the substrate 1. The film thickness of the first electrode 2 is, for example, from 100 to 1000 nm, both inclusive.

(Intermediate Layer)

An intermediate layer not illustrated in FIG. 1 may be provided between the first electrode 2 and the light-absorbing layer 3 of the photoelectric conversion element 100 of the embodiment. The intermediate layer is a layer formed on a principal plane on the first electrode 2 at an opposite side to the substrate 1. In the photoelectric conversion element 100 of the embodiment, by providing the intermediate layer between the first electrode 2 and the light-absorbing layer 3, contact between the first electrode 2 and the light-absorbing layer 3 is improved. With the improvement of contact, Voc of the photoelectric conversion element, that is, a voltage is improved, and conversion efficiency is improved. The intermediate layer contributes not only to the conversion efficiency but also to peeling resistance of the light-absorbing layer 3. In a case where the first electrode 2 is the first metal film, the intermediate layer is an oxide or sulfide film containing at least one metal selected from the group consisting of; Mg, Ca, Al, Ti, Ta, and Sr. The oxide film or the sulfide film may be independently used, or a layer in which the oxide film and the sulfide film are laminated may be used. The intermediate layer of the case where the first electrode 2 is the first metal film is favorably a thin film made of a material use for a tunnel insulating film. Specific examples of the intermediate layer of the case where the first electrode 2 is the first metal film include metal oxides such as MgO, CaO, Al₂O₃, TiO₂, Ta₂O₅, SrTiO₃, Mlo₃, and CdO and metal sulfides such as ZnS, MgS, CaS, Al₂S₃, TiS₂, Ta₂S₅, SrTiS₃, and CdS.

Further, in a case where the first electrode 2 is the semiconductor film, the intermediate layer is favorably a second metal film, or a laminated body having an oxide film, a sulfide film, or a selenide film on the second metal film. Note that, in a case of the laminated body, the intermediate layer has the second metal film on a side of the first electrode 2, and the oxide film, the sulfide film, or the selenide film on the second metal film on a side of the light-absorbing layer 3. The oxide film, the sulfide film, or the selenide film is an oxide or sulfide film containing at least one element selected from the group consisting of; from Mg, Ca, Al, Ti, Ta, and Sr. The oxide film, the sulfide film, or the selenide film may be independently used, or a layer in which these films are laminated may be used. The second metal film of the intermediate layer of a case where the lower electrode 2 is the semiconductor film is a film containing Mo or W, for example, and is favorably an Mo film or a W film.

(Light-Absorbing Layer)

The light-absorbing layer 3 of the embodiment is a compound semiconductor layer. The light-absorbing layer 3 is a layer formed on the first electrode 2, or on a principal plane on the intermediate layer at an opposite side to the substrate 1. A compound semiconductor layer having a chalcopyrite structure containing a group Ib element, a group IIIb element, and a group VIb element, such as Cu(In, Ga) Se₂, CuInTe₂, CuGaSe₂, Cu(In, Al) Se₂, Cu(Al, Ga) (S, Se)₂, CuGa(S, Se)₂, or Ag(In, Ga) Se₂, can be used as the light-absorbing layer. Favorably, the group Ib element is Cu, Ag, or both of Cu and Ag, the group IIIb element includes at least one metal selected from the group consisting of; Ga, Al, and In, and the group VIb element includes at least one element selected from the group consisting of; Se, S, and Te. Among them, more favorably, the group Ib element is Cu, Ag, or both of Cu and Ag, the group IIIb element is Ga, Al, or Ga and Al, and the group VIb element is Se, S, or Se and S. It is favorable if the group IIIb element contains less In because a band gap of the light-absorbing layer 3 can be easily adjusted to a favorable value as a top cell of the multijunction-type photoelectric conversion element. The film thickness of the light-absorbing layer 3 is, for example, from 800 to 3000 nm, both inclusive.

The light-absorbing layer 3 has a problem that short-circuit current density Jsc becomes large, but an open circuit voltage Voc is smaller than a theoretical value, if a region having good crystallinity (a region having uniform composition) is thick. Therefore, in the light-absorbing layer 3 of the embodiment, a region in which a part of the group Ib element is lost (a region having a high loss ratio of the group Ib element) is provided in an extremely thin manner near an interface on a side of the n region in a case of a homojunction-type layer, or near an interface on a side of the n layer 4 in a case of a heterojunction-type layer, so that both high short-circuit current density and a high open circuit voltage are achieved. The light-absorbing layer 3 is favorably formed by a vapor deposition method described below.

By providing the region having a high loss ratio of the group Ib element in an extremely thin manner, a region having concentration of the group Ib element in the light-absorbing layer being 0.1 to 10 atom %, both inclusive, is included in a region up to the depth of 10 nm in a direction from a principal plane of the light-absorbing layer 3 on the side of the second electrode 5 to the side of the first electrode 2. In such a region, it is favorable to include a region having the concentration of the group Ib element in the light-absorbing layer being 2.5 atom % or more. The inclusion of such a region indicates that the region having high loss ratio of the group Ib element exists in the light-absorbing layer 3 on the side of the second electrode 5, and can achieve both the high short-circuit current density and the high open circuit voltage. Then, average concentration of Ib elements in the light-absorbing layer being 0.1 to 10 atom %, both inclusive, is favorable in a region up to the depth of 5 nm in the direction from the principal plane of the light-absorbing layer 3 on the side of the second electrode 5 to the side of the first electrode 2, from a viewpoint of achievement of both the high short-circuit current density and the high open circuit voltage.

Further, if the region having a high loss ratio of the group Ib element is too thick, the short-circuit current density is decreased due to recombination in the region having a high loss ratio. Therefore, to cause the region having a high loss ratio of the group Ib element to exist only in the extremely thin region, the average concentration of Ib elements in the light-absorbing layer is favorably from 5 to 30 atom %, both inclusive, in a region from the depth of 5 nm in the direction from the principal plane of the light-absorbing layer 3 on the side of the second electrode 5 to the side of the first electrode 2 to the depth of 10 nm in the direction from the principal plane of the light-absorbing layer 3 on the side of the second electrode 5 to the side of the first electrode 2.

Further, good crystallinity of the light-absorbing layer 3 in a central portion of the light-absorbing layer 3 in a thickness direction is favorable from a viewpoint to obtain the photoelectric conversion element having high short-circuit current density. Therefore, the average concentration of Ib elements in the light-absorbing layer being from 15 to 35 atom %, both inclusive, is favorable in a region from the depth of 45 nm in the direction from the principal plane of the light-absorbing layer 3 on the side of the second electrode 5 to the side of the first electrode 2 to the depth of 50 nm in the direction from the principal plane of the light-absorbing layer 3 on the side of the second electrode 5 to the side of the first electrode 2. Further, from the same viewpoint, the average concentration of Ib elements in the light-absorbing layer being from 15 to 35 atom %, both inclusive, is favorable in a region from the depth of ¼d in the direction from the principal plane of the light-absorbing layer 3 on the side of the second electrode 5 to the side of the first electrode 2 to the depth of ¾d from the principal plane of the light-absorbing layer 3 on the side of the second electrode 5 to the side of the first electrode 2, where the thickness of the light-absorbing layer 3 is d.

Atomic concentration of the group Ib element in the light-absorbing layer 3 is obtained by the method below. Elements of the light-absorbing layer 3 are analyzed in a film thickness direction using 3D atom probe. The elements contained in the light-absorbing layer 3 are quantized and determined in advance, by narrowing down candidates of the elements contained in the light-absorbing layer 3 using a scanning electron microscope-energy dispersive X-ray spectroscope (SEM-EDX), and dissolving powder of the light-absorbing layer 3, which is obtained by grinding off the central portion of the light-absorbing layer 3 in the film thickness direction, into an acid solution, and analyzing the solution by inductively coupled plasma (ICP). Note that the elements contained in the light-absorbing layer 3 are elements having the concentration of 1 atom % or more, of the candidate elements narrowed down by the SEM-EDX and analyzed by ICP.

As a sample for the 3D atom probe analysis, a sharp needle-like sample having an end diameter of 10 nm is prepared. A needle-like sample having a length longer than the region to be analyzed, which is suitable for the analysis, is prepared. The light-absorbing layer 3 at the side of the first electrode is a tip end of the needle-like sample. Five needle-like samples are prepared for one photoelectric conversion element to be analyzed. The five samples are obtained such that the principal plane of the light-absorbing layer is equally divided into four regions in a grid manner, and four points in the centers of the divided regions and one point in the center of the principal plane of the light-absorbing layer 3 are employed, and a length direction of the needle-like sample is a vertical direction with respect to the principal plane of the light-absorbing layer 3. In a case where the n layer 4 is included in the photoelectric conversion element 100, the n layer 4 is included in the region to be analyzed of the needle-like sample. Further, in a case where the n layer 4 is not included in the photoelectric conversion element 100, a layer on the side of the second electrode 5, where the light-absorbing layer 3 forms an interface, is included in the region to be analyzed of the needle-like sample.

For the 3D atom probe, LEAP4000X Si manufactured by AMETEK was used and the analysis was conducted under conditions in which a measurement mode is Laser pulse, laser power is 35 pJ, and the temperature of the needle-like sample is 70 K. Note that, in the case of heterojunction type, an interface between the light-absorbing layer 3 and the n layer 4 is the principal plane of the light-absorbing layer 3 on the side of the second electrode 5. In the case of the heterojunction type, the principal plane of the light-absorbing layer 3 on the side of the second electrode 5 is a point where signal intensity of an element contained in the n layer 4 but not contained in the light-absorbing layer 3 exceeds signal intensity of the group Ib element of the light-absorbing layer 3 for the first time. In the case of the homojunction type, an interface between the layer (for example, the second electrode 5) forming a junction with the light-absorbing layer 3 on the side of the second electrode 5, and the light-absorbing layer 3 is the principal plane of the light-absorbing layer 3 on the side of the second electrode 5. In the case of the homojunction type, the principal plane of the light-absorbing layer 3 on the side of the second electrode 5 is a point where the signal intensity of an element contained in a layer on the side of the second electrode 5, where the light-absorbing layer 3 forms an interface, but not contained in the light-absorbing layer 3 exceeds the signal intensity of the group Ib element of the light-absorbing layer 3 for the first time. Here, the signal intensity refers to a state where a detected element is converted into atom %. The analysis is performed up to the depths of 5 nm, 10 nm, and 50 nm from the principal plane of the light-absorbing layer 3 on the side of the second electrode 5 according to the purpose.

As for a result of the 3D atom probe, an average value of results of the five needle-like samples is employed as an analysis value. The result measured in the region of the light-absorbing layer 3 includes a component of noises and the like. Therefore, signals not included in the light-absorbing layer 3 are removed such that the atomic weight of the element confirmed to be contained in the light-absorbing layer 3 by ICP becomes 100 atom %, in a point of 50 nm from the interface between the light-absorbing layer 3 and the n layer 4 (or a layer where the light-absorbing layer 3 forms an interface on the side of the second electrode 5) to the side of the first electrode 2, and atom % of the group Ib element, atom % of the group IIIb element, and atom % of the group VIb element were obtained.

In the vapor deposition method described below, a method of forming a CGS layer in which the group Ib element is Cu, the group IIIb element is Ga, and the group VIb element is Se will be exemplarily described. In a case of using other elements, a layer can be similarly formed to the vapor deposition method below.

In the vapor deposition method (three-step method), first, the temperature of a substrate (a member in which the first electrode 2 is formed on the substrate 1) is heated to from 200 to 400° C., both inclusive, and Ga (group IIIb element) and Se (group VIb element) are deposited while confirming two to four fringes due to change of the film thickness with a pyrometer (first step). The time is desirably from 5 to 50 minutes, both inclusive, although depending on a film forming rate.

After that, the temperature of the substrate 1 is heated to from 300 to 550° C., both inclusive, and Cu (group Ib element) and Se are deposited. Start of an endothermic reaction is confirmed, and the deposition of Cu and Se is stopped at the composition where Cu becomes excessive (second step). After the start of an endothermic reaction, Cu and Se are excessively deposited for a time of about 5% or more of a Cu supply time, so that crystal quality is enhanced, and thus this is desirable. Although depending on the film forming rate, the deposition time of Cu and Se is desirably from 30 to 120 minutes, both inclusive. If the deposition time is too short, the Cu supply rate becomes too fast, and there is a decrease in the crystal quality. On the other hand, if the deposition time is too long, breakdown of the lower electrode and the substrate may occur.

After the second step, Ga and Se are deposited attain (third step), so that the composition is made to a Ga-slightly excessive composition, and the deposition of Ga is stopped. Due to the deposition of Ga and Se in the third step, the substrate temperature rises again, and becomes from 300 to 550° C., both inclusive. The deposition time of Ga and Se is desirably from 1 to 9 minutes, both inclusive.

Then, annealing is performed while irradiating the substrate with Se while maintaining the substrate temperature to from 300 to 550° C., both inclusive. The annealing time is favorably from 0 to 60 minutes, both inclusive (fourth step). By performing the processing of the fourth step, uniformity of the composition of the light-absorbing layer 3 is improved, and the crystallinity of the light-absorbing layer 3 is improved.

After termination of the fourth step, the substrate temperature is cooled to from 250 to 400° C., both inclusive, and Ga an Se are deposited (fifth step). The fifth step is a process of forming a region having a high loss ratio of Cu. If the substrate temperature is too low, the film quality of the region having a high loss ratio of Cu, the region being mainly formed of Ga and Se, is decreased. If the film quality of the region having a high loss ratio of Cu is decreased, recombination of an electron and a hole is increased and the short-circuit current density is decreased in the light-absorbing layer 3 even if the region is thin, and thus this is not favorable. From the viewpoint, the substrate temperature is more favorably 300° C. or more. Further, if the substrate temperature is too high, Cu is more likely to be dispersed in the region formed in the fifth step, and the loss ratio of Cu is decreased. Therefore, this is not favorable. If the deposition time of the fifth step is long, the region having a high loss ratio of Cu becomes thick, and the short-circuit current density is decreased. Therefore, the deposition time of the fifth step is favorably from 5 to 30 seconds, both inclusive, although depending on a temperature condition. Further, when performing the process of the fifth step at a high temperature where the substrate temperature is about 400° C., as the deposition time of the fifth step, it is more favorable to select a short time within the above-described time range. If the deposition time of the fifth step is too long, the region having a high loss ratio of Cu is too thick, and the recombination of an electron and a hole is increased and the short-circuit current density is decreased. Therefore, this is not favorable. By the process of the fifth step, the light-absorbing layer 3 including the region where the concentration of the group Ib element in the chalcopyrite-type compound is from 0.1 to 10 atom %, both inclusive, can be obtained in the region up to the depth of 10 nm in the direction from the principal plane of the light-absorbing layer 3 on the side of the second electrode 5 to the side of the first electrode 2.

In the case where the light-absorbing layer 3 is the homojunction-type layer, examples of a method of doping a part of the light-absorbing layer 3 with an n-type layer include a dipping method, a spray method, a spin coating method, and a vapor method. In the dipping method, for example, the light-absorbing layer 3 is dipped from the principal plane at an opposite side to the side of the substrate 1 into a solution (for example, sulfate aqueous solution) containing any of cadmium (Cd), zinc (Zn), Mg, or Ca that is an n dopant and having the temperature of from 10 to 90° C., both inclusive, and the solution is stirred for about 25 minutes. The processed member is taken out of the solution, the surface is washed with water, and the processed member is favorably dried.

(n Layer)

Then layer 4 of the embodiment is an n-type semiconductor layer. The n layer 4 is a layer forming a heterojunction with the first electrode 2 on the light-absorbing layer 3 or the light-absorbing layer 3 formed on the side of the principal plane at an opposite side to the intermediate layer 3. Note that, in a case where the light-absorbing layer 3 is the homojunction-type layer, the n layer 4 is omitted. The n layer 4 is favorably an n-type semiconductor in which a Fermi level is controlled to obtain a photoelectric conversion element having a high open circuit voltage. As the n layer 4, for example, Zn_{1-y}M_{y}O₁₋ₓSₓ, Zn_{1-y-z}Mg_{z}M_{y}O, ZnO₁₋ₓSₓ, Zn_{1-z}Mg_{z}O (M is at least one selected from the group consisting of; B, Al, In, and Ga), CdS, or an n-type GaP in which carrier concentration is controlled can be used. The thickness of the n layer 4 is favorably from 2 to 800 nm, both inclusive. The n layer 4 is, for example, formed by sputtering or a chemical bath deposition method (CBD). In a case of forming the n layer 4 by the CBD, for example, a metal salt (for example, CdSO₄), sulfide (thiourea), and a complexing agent (ammonia) can be formed on the light-absorbing layer 3 in an aqueous solution by a chemical reaction. In a case of using a chalcopyrite-type compound not including In in the group IIIb element, such as a CuGaSe₂ layer, an AgGaSe₂ layer, a CuGaAlSe layer, or a CuGa(Se, S)₂ layer, as the light-absorbing layer 3, CdS is favorable as the n layer 4.

(Oxide Layer)

An oxide layer of the embodiment is a thin film favorable to be provided between the n layer 4 and the second electrode 5 or between the light-absorbing layer 3 and the second electrode 5. The oxide layer is a thin film containing a compound of any of Zn₁₋ₓMgₓO, ZnO_{1-y}S_{y}, and Zn₁₋ₓMgₓO_{1-y}S_{y} (0≦x, y<1). The oxide layer may have a form not coating all of a principal plane of the n layer 4 on the side of the second electrode 5. For example, the oxide layer may coat 50% of the surface of the n layer 4 on the side of the second electrode 5. Examples of other candidates include wurtzite-type AlN, GaN, and BeO. If volume resistivity of the oxide layer is 1 Ωcm or more, there is an advantage that a leak current deriving from a low resistance component that may exist in the light-absorbing layer 3 can be suppressed. Note that, in the embodiment, the oxide layer may be omitted.

(Second Electrode)

The second electrode 5 of the embodiment is an electrode film that transmits light such as solar light and has conductivity. The second electrode 5 is formed by sputtering in an Ar atmosphere. As the second electrode 5, ZnO:Al using a ZnO target containing 2 wt % of alumina (Al₂O₃), or ZnO:B using B from diborane or triethyl boron as a dopant can be used.

(Third Electrode)

A third electrode of the embodiment is an electrode of the photoelectric conversion element 100, and is a metal film formed on the second electrode. As the upper electrode 8, a conductive metal film made of Ni or Al can be used. The film thickness of the third electrode is from 200 to 2000 nm, both inclusive, for example. Further, in a case where a resistance value of the second electrode is low and a series resistance component is ignorable, the third electrode may be omitted.

(Antireflective Film)

An antireflective film of the embodiment is a film for ease of introduction of light into the light-absorbing layer 3, and is formed on the second electrode 5 or the third electrode. As the antireflective film, for example, MgF₂ or SiO₂ is desirably used. Note that, in the embodiment, the antireflective film can be omitted.

(Solar Battery Module)

A solar battery of the embodiment can be used as a power generation element in a solar battery module. The solar battery of the embodiment is one in which the photoelectric conversion element of the embodiment receives light and generates electricity, and generated power is consumed in a load electrically connected with the solar battery or is stored in a storage battery electrically connected with the solar battery.

Examples of the solar battery module of the embodiment include a member in which a plurality of cells of the solar battery is connected in series, in parallel, or in series and parallel, or a structure in which a single cell is fixed to a support member made of glass or the like. The solar battery module may be provided with a light condenser and have a configuration to convert light received in a larger area than areas of the cells of the solar battery into power.

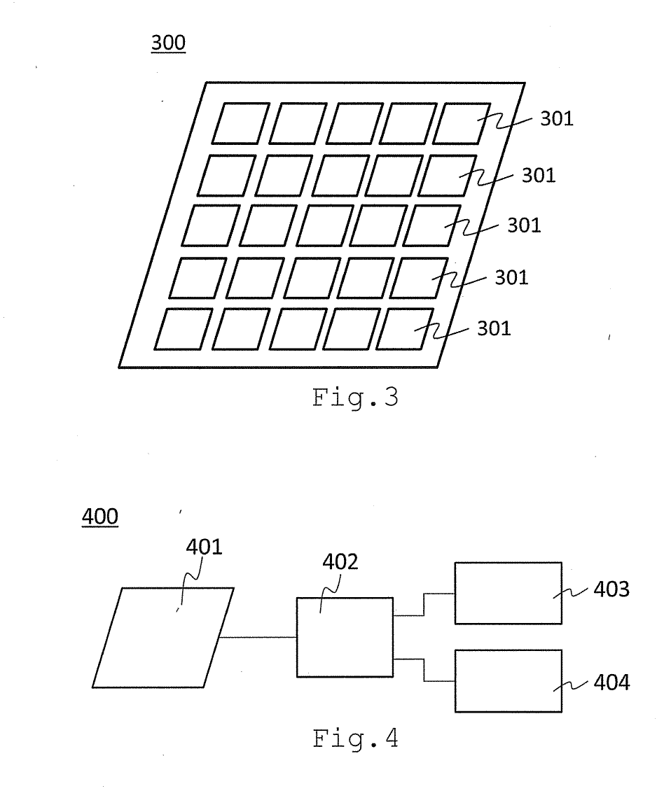

FIG. 3 illustrates a configuration conceptual diagram of a solar battery module 300 in which five solar battery cells 301 are arranged in a cross direction, and five cells are arranged in a longitudinal direction. In the solar battery module 300 of FIG. 3, the plurality of solar battery cells 301 is favorably connected in series, in parallel, or in series and parallel, as described above, although connection wiring is omitted. As the solar battery cell 301, the photoelectric conversion element 100 of the embodiment, that is, the solar battery is favorably used. Further, as the solar battery cell 301, a solar battery that is a multifunction-type photoelectric conversion element in which the photoelectric conversion element 100 of the embodiment and another photoelectric conversion element 200 are joined can be favorably used. Further, as the solar battery module 300 of the embodiment, a module structure in which a module using the photoelectric conversion element 100 of the embodiment and a module using the other photoelectric conversion element 200 are layered may be employed. In addition, a structure that enhances the conversion efficiency is favorably employed. In the solar battery module 300 of the embodiment, the solar battery cell 301 includes a photoelectric conversion layer with a wide band gap, and thus is favorably provided on a side of a light-receiving surface.

(Solar Power Generation System)

The solar battery module 300 of the embodiment can be used as a generator that generates electricity in a solar power generation system. The solar power generation system of the embodiment generates electricity using the solar battery module, and to be specific, includes a solar battery module that generates electricity, means that converts the generated electricity into power, and storage means that stores the generated electricity or a load that consumes the generated electricity. FIG. 4 illustrates a configuration conceptual diagram of a solar power generation system 400 of an embodiment. The solar power generation system of FIG. 4 includes a solar battery module 401 (300), a converter 402, a storage battery 403, and a load 404. One of the storage battery 403 and the load 404 may be omitted. The load 404 may be configured to use electric energy stored in the storage battery 403. The converter 402 is a device including a circuit or an element such as a DC-DC converter, a DC-AC converter, or an AC-AC converter that performs power conversion such as voltage transformation or AC-DC conversion. As the configuration of the converter 402, a favorable configuration may just be employed according to a generation voltage, and the configurations of the storage battery 403 and the load 404.

The light received the solar battery cell 301 of the solar battery module 300 generates electricity, and the electric energy is converted in the converter 402 and is stored in the storage battery 403 or consumed in the load 404. The solar battery module 401 is favorably provided with a solar light tracking drive device for causing the solar battery module 401 to face the sun on a constant basis, a light condenser that condenses the solar light, and a device that improves power generation efficiency.

The solar power generation system 400 is favorably used in an immovable property such as a residence, a commercial facility, or a factory, or is favorably used in movable property such as a vehicle, an aircraft, or an electronic device. By use of the photoelectric conversion element excellent in the conversion efficiency of the embodiment for the solar battery module 401, an increase in a power generation amount can be expected.

Hereinafter, the present embodiment will be more specifically described on the basis of examples.

### Example 1

A lamination electrode containing respective compounds of SiO₂-ITO-SnO₂ was formed on a substrate made of soda-lime glass and having dimensions of height 16 mm×width 12.5 mm×thickness 1.8 mm by sputtering in the order of SiO₂-ITO-SnO₂ from a substrate side. The film thickness is, in order from the substrate side, 10 nm, 150 nm, and 100 nm. Next, the light-absorbing layer was formed on the lamination electrode by a vapor deposition method. First, the substrate temperature was heated to 380° C., and Ga and Se were deposited for 25 minutes (first step). After that, the substrate temperature was heated up to 490° C., and Cu and Se were deposited. When the start of an endothermic reaction was confirmed, Cu and Se were continuously deposited for a time of 10% of the time during which Cu an Se were deposited before the start of an endothermic reaction. Then, the deposition of Cu is stopped in a Cu-excessive composition (second step). The substrate temperature at this time was 465° C. After the stop of deposition, Ga and Se were deposited again (third step), so that the composition becomes a group IIIb element-slightly excessive composition. Due to the deposition in the third step, the substrate temperature rose to 480° C. Annealing was performed for 60 minutes in a state of irradiating the substrate with Se so that Ga and Se deposited in the third step react with Cu an Se deposited in the second step to form CuGaSe₂ (fourth step). Then, the substrate was cooled, and Ga and Se were deposited again when the substrate temperature become 330° C. (fifth step). The deposition time at this time was 30 seconds. Then, the light-absorbing layer 3 having the film thickness of 1500 nm was formed. An n-CdS layer was deposited as an n-type semiconductor layer on the obtained p-type semiconductor layer as the light-absorbing layer by solution growth. 0.002 M of cadmium sulfate was added to ammonia water that was heated to 67° C., and the member deposited up to the light-absorbing layer was dipped in the solution. The dipping was performed such that the surface on the side of the light-absorbing layer is dipped. Three minutes later, 0.05 M of thiourea was added, and a reaction was conducted for 150 seconds, so that the n-CdS layer having the film thickness of 10 nm was formed as the n layer on the light-absorbing layer. Then, as a transparent electrode, (Zn, Mg) O:Al was formed by 100 nm, and the photoelectric conversion element of Example 1 was obtained.

After the formation of the light-absorbing layer, the sample in production was taken out, the atomic concentration of the group Ib element of the region up to the depth of 5 nm from a surface was analyzed by an X-ray photoelectron spectroscopy (XPS), and average atomic concentration of the group Ib elements in the region up to the depth of 5 nm from the surface of the light-absorbing layer was obtained. The measurement up to 5 nm from the surface by the XPS took a roughly close value to the atomic concentration of the group Ib element in analyzing the region up to 5 nm from the interface between the light-absorbing layer and the n layer toward the first electrode direction, which is an analysis of the needle-like sample manufactured from the photoelectric conversion element 100 by the 3D atom probe.

Further, the needle-like samples were produced from the photoelectric conversion element 100, and the average concentration of the Ib elements in the region up to the depth of 5 nm in the direction from the interface between the light-absorbing layer and the n layer to the side of the first electrode by the 3D atom probe X 5, the average concentration of the group Ib elements in the region from the depth of 5 nm to the depth of 10 nm in the direction from the interface between the light-absorbing layer and the n layer to the first electrode X 10, and the average concentration of the group Ib elements in the region from the depth of 45 nm to the depth of 50 nm in the direction from the interface between the light-absorbing layer and the n layer to the first electrode X 50 were obtained by the above-described method.

The produced open end voltage (Voc), the short-circuit current density (Jsc), and the fill factor FF were measured, and the conversion efficiency η was obtained. Under irradiation of AM 1.5 of simulate solar light with a solar simulator, a voltage source and a multimeter were used, the voltage of the voltage source was changed, the voltage at which the current becomes 0 mA under the irradiation of the simulated solar light was measured, and the open end voltage (Voc) was obtained. No voltage was applied, the current at the time of short circuit was measured, and the short-circuit current density (Jsc) was obtained. Table 1 illustrates the short-circuit current density Jsc, the open circuit voltage Voc, the conversion efficiency, the atomic concentration of the group Ib element in the region up to 5 nm from the surface by the XPS, the atomic concentration of the group Ib element by the analysis of the 3D atom probe, of Examples of Comparative Examples. Note that the region having the Cu concentration of 0.1 to 10 atom %, both inclusive, being included in the region up to the depth of 10 nm from the surface of the light-absorbing layer has been confirmed by the 3D atom probe.

### Examples 2 to 19 and Comparative Examples 1 to 9

The photoelectric conversion elements of Examples 2 to 19 and Comparative Examples 1 to 9 were similarly obtained to Example 1 under the configurations and conditions described in Table 1. The light-absorbing layers 3 were similarly formed by selecting the group Ib element, the group IIIb element, and the group VIb element to have the compounds in Table 1. As for the light-absorbing layers of a part of Comparative Examples, the photoelectric conversion elements were obtained such that the second electrode was formed on the substrate on which the processing up to the third step had been performed. The analysis by the 3D atom probe was performed only for a part of Examples and Comparative Examples.

TABLE 1A

| | | Fifth step | | | |
|---|---|---|---|---|---|
| | Light- | Temper- | | Conver- | |
| | absorbing | ature | Time | sion effi- | Voc |
| | layer | (° C.) | (second) | ciency % | (V) |
| Example 1 | CuGaSe₂ | 330 | 30 | 7.8 | 0.84 |
| Example 2 | CuGaSe₂ | 400 | 30 | 7.8 | 0.80 |
| Example 3 | CuGaSe₂ | 370 | 30 | 7.9 | 0.82 |
| Example 4 | CuGaSe₂ | 290 | 30 | 7.0 | 0.77 |
| Example 5 | CuGaSe₂ | 400 | 15 | 8.8 | 0.72 |
| Example 6 | CuGaSe₂ | 390 | 15 | 8.1 | 0.75 |
| Example 7 | CuGaSe₂ | 380 | 15 | 7.9 | 0.77 |
| Example 8 | CuGaSe₂ | 400 | 7 | 8.2 | 0.71 |
| Example 9 | CuGaSe₂ | 370 | 7 | 8.4 | 0.73 |
| Example 10 | CuGaSe₂ | 330 | 7 | 8.3 | 0.75 |
| Example 11 | Cu(Ga,Al)Se₂ | 390 | 15 | 7.5 | 0.81 |
| Example 12 | Cu(Ga,Al)Se₂ | 370 | 30 | 7.7 | 0.85 |
| Example 13 | Cu(Ga,Al)Se₂ | 370 | 7 | 8.1 | 0.81 |
| Example 14 | CuGa(Se,S)₂ | 370 | 7 | 7.9 | 0.78 |
| Example 15 | AgGaSe₂ | 370 | 7 | 7.0 | 0.79 |
| Example 16 | CuGa(S,Te)₂ | 330 | 30 | 7.6 | 0.79 |
| Example 17 | Cu(In,Ga)S₂ | 370 | 7 | 6.7 | 0.87 |
| Example 18 | Cu(In,Ga)Se₂ | 330 | 30 | 7.9 | 0.80 |
| Example 19 | Cu(In,Ga)Se₂ | 400 | 30 | 8.2 | 0.75 |
| Example 20 | Cu(In,Ga)Se₂ | 370 | 30 | 8.0 | 0.76 |
| Comparative | CuGaSe₂ | — | — | 7.7 | 0.75 |
| Example 1 | | | | | |
| Comparative | CuGa(Se,S)₂ | — | — | 7.5 | 0.76 |
| Example 2 | | | | | |
| Comparative | AgGaSe₂ | — | — | 6.5 | 0.81 |
| Example 3 | | | | | |
| Comparative | Cu(Ga,Al)Se₂ | — | — | 7.0 | 0.80 |
| Example 4 | | | | | |
| Comparative | CuGaSe₂ | 470 | 30 | 7.6 | 0.69 |
| Example 5 | | | | | |
| Comparative | CuGaSe₂ | 230 | 40 | 0.18 | 0.35 |
| Example 6 | | | | | |
| Comparative | CuGa(S,Te)₂ | — | — | 7.3 | 0.72 |
| Example 7 | | | | | |
| Comparative | Cu(In,Ga)S₂ | — | — | 6.5 | 0.85 |
| Example 8 | | | | | |
| Comparative | Cu(In,Ga)Se₂ | — | — | 7.6 | 0.73 |
| Example 9 | | | | | |

TABLE 1B

| | | Group Ib | | | |
|---|---|---|---|---|---|
| | | element | X50 | X10 | X5 |
| | Jsc | concentration | (atom | (atom | (atom |
| | (mA/cm²) | (atom %) | %) | %) | %) |
| Example 1 | 17.6 | 4.2 | 26 | 14 | 5 |
| Example 2 | 18.3 | 7.4 | — | — | — |
| Example 3 | 17.9 | 6.6 | — | — | — |
| Example 4 | 17.2 | 2.5 | — | — | — |
| Example 5 | 19.1 | 9.1 | — | — | — |
| Example 6 | 18.0 | 7.7 | — | — | — |
| Example 7 | 17.3 | 7.6 | 23 | 20 | 9 |
| Example 8 | 19.3 | 10.5 | — | — | — |
| Example 9 | 18.9 | 9.8 | — | — | — |
| Example 10 | 18.8 | 9.6 | — | — | — |
| Example 11 | 16.8 | 9.4 | — | — | — |
| Example 12 | 17.0 | 5.4 | — | — | — |
| Example 13 | 17.8 | 9.5 | — | — | — |
| Example 14 | 16.7 | 9.9 | — | — | — |
| Example 15 | 15.8 | 9.8 | — | — | — |
| Example 16 | 17.2 | 4.1 | — | — | — |
| Example 17 | 13.9 | 9.5 | — | — | — |
| Example 18 | 17.0 | 4.5 | — | — | — |
| Example 19 | 17.8 | 8.2 | — | — | — |
| Example 20 | 17.1 | 7.1 | — | — | — |
| Comparative | 17.5 | 11.0 | 24 | 15 | 11 |
| Example 1 | | | | | |
| Comparative | 16.9 | 10.8 | — | — | — |
| Example 2 | | | | | |
| Comparative | 16.3 | 11.9 | — | — | — |
| Example 3 | | | | | |
| Comparative | 16.2 | 11.2 | — | — | — |
| Example 4 | | | | | |
| Comparative | 19.2 | 11.4 | — | — | — |
| Example 5 | | | | | |
| Comparative | 2.1 | 0.0 | — | — | — |
| Example 6 | | | | | |
| Comparative | 18.5 | 10.6 | — | — | — |
| Example 7 | | | | | |
| Comparative | 14.8 | 11.8 | — | — | — |
| Example 8 | | | | | |
| Comparative | 18.1 | 11.7 | — | — | — |
| Example 9 | | | | | |

When confirming the region having the Cu concentration of 0.1 to 10 atom % being included in the region up to the depth of 10 nm from the surface of the light-absorbing layer by the 3D atom probe, the region was confirmed in Example 7 but not confirmed in Comparative Example 1.

Making comparison with Comparative Example 1 without the fifth step, Examples 1 to 4 (fifth step) have improvement of the open circuit voltage due to the existence of the Cu loss layer. Meanwhile, Examples 1 to 4 have a tendency of a slight decrease in the short-circuit current density. The concentration of the group Ib element by the XPS is also smaller than that of Comparative Example 1. Dispersion of the group Ib (Cu) is suppressed by the low-temperature film formation. However, when the fifth step is too high (Comparative Example 5), there is no improvement of the open circuit voltage, and the group Ib (Cu) is dispersed up to the interface on the side of the transparent electrode (n side) of the CGS due to post-annealing. This suggests that the group Ib is dispersed up to the surface due to the post-annealing of the fourth step, and it can be considered that dispersion of Cu to the outermost surface, the Cu having been dispersed up to the surface by the fifth step performed afterward, is suppressed. That is, it can be considered that both the short-circuit current density and the open circuit voltage are achieved by making the layer immediately before the outermost surface layer with the CGS layer, and only the outermost surface layer with the thin Cu (a large amount of) loss layer. There are similar tendencies in Examples 5 to 9, and a decrease in the short-circuit current density is small by the thinner thickness of the Cu (a large amount of) loss layer. Optimization can be performed by adjusting the temperature, the time, and the film formation rate. By selecting a condition, the time of the fifth step can be shortened to one second or less. Further, the effect of the fifth step can be confirmed in the layers other than CuGaSe₂ from Examples 11 to 20 and Comparative Examples 2 to 9. The effect of the fifth step is to exhibit favorable change in a solar battery characteristic by manufacturing a layer other than the typically employed outermost layer of CuGa₃Se₅ layer (Cu loss layer). That is, when the vapor deposition process of the fifth step is performed, the effect can be exhibited as long as the Cu amount in the element is from 1/(1+3+5) to 11.1 atom %, exclusive of 11.1.

In the specification, a part of elements is expressed only by symbols for the elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion element comprising:
a first electrode;
a second electrode; and
a light-absorbing layer containing a chalcopyrite-type compound containing a group Ib element, a group IIIb element, and a group VIb element between the first electrode and the second electrode, wherein
a region in which concentration of the group Ib element in the light-absorbing layer is from 0.1 to 10 atom %, both inclusive, is included in a region up to a depth of 10 nm in a direction from a principal plane of the light-absorbing layer on a side of the second electrode to a side of the first electrode.

2. The element according to claim 1, wherein average concentration of Ib elements in the light-absorbing layer is from 0.1 to 10 atom %, both inclusive, in a region up to the depth of 5 nm in the direction from a principal plane of the light-absorbing layer on a side of the second electrode to a side of the first electrode.

3. The element according to claim 1, wherein average concentration of Ib elements in the light-absorbing layer is from 5 to 30 atom %, both inclusive, in a region from the depth of 5 nm in the direction from a principal plane of the light-absorbing layer on a side of the second electrode to a side of the first electrode to the depth of 10 nm in the direction from a principal plane of the light-absorbing layer on a side of the second electrode to a side of the first electrode.

4. The element according to claim 1, wherein average concentration of Ib elements in the light-absorbing layer is from 15 to 35 atom %, both inclusive, in a region from the depth of 45 nm in the direction from a principal plane of the light-absorbing layer on a side of the second electrode to a side of the first electrode to the depth of 50 nm in the direction from a principal plane of the light-absorbing layer on a side of the second electrode to a side of the first electrode.

5. The element according to claim 1, wherein
the group Ib element is Cu, Ag, or both of Cu and Ag,
the group IIIb element is at least one metal selected from the group consisting of; from Ga, Al, and In, and
the group VIb element is at least one element selected from the group consisting of; Se, S, and Te.

6. A photoelectric conversion element using the photoelectric conversion element according to claim 1 as a multijunction-type photoelectric conversion element.

7. A solar battery using the photoelectric conversion element according to claim 1.

8. A solar battery using the photoelectric conversion element according to claim 6.

9. A solar battery module using the solar battery according to claim 7.

10. A solar battery module using the solar battery according to claim 8.

11. A solar power generation system adapted to generate electricity using the solar battery module according to claim 9.

12. A solar power generation system adapted to generate electricity using the solar battery module according to claim 10.
